(19) United States
(12) Patent Application Publication
(10) Pub. No.: US 2026/0245826 A1
(43) Pub. Date: Aug. 20, 2026

(54) SCANNING ELECTRON MICROSCOPE AND METHODS FOR EVALUATING PROPERTIES OF A SAMPLE THEREWITH

(71) Applicant: Applied Materials Israel Ltd., Rehovot (IL)

(72) Inventors: Miriam Brook, Kramim (IL); Dror Shemesh, Hod Hasharon (IL)

(73) Assignee: Applied Materials Israel Ltd., Rehovot (IL)

(21) Appl. No.: 19/057,958

(22) Filed: Feb. 19, 2025

(51) Int. Cl. H01J 37/147; H01J 37/10; H01J 37/28

(52) U.S. Cl. CPC H01J 37/1471; H01J 37/28; H01J 37/10

(57) ABSTRACT

A scanning electron microscope (SEM) is provided, configured to evaluate one or more properties of a sample comprising a plurality of repeating features. The SEM comprises a scanning arrangement to scan a site on the sample by irradiating it with source particles and detecting resulting signals, and a controller to operate the SEM and evaluate properties at the site based on the signals. The scanning arrangement scans equivalent sites of interest on the features for a scan-duration which is less than an acquisition-duration necessary for evaluation of a property of interest. The sum of the scan-durations is no less than the acquisition-duration. The controller aggregates measurements of the detected signals produced by each of the equivalent sites of interest, and evaluates one or more predetermined properties of the sites of interest on the plurality of repeating features based at least partially on the aggregated measurements.

### TECHNICAL FIELD

The presently disclosed subject matter relates to inspection systems configured to evaluate one or more properties of a sample by detecting particles emitted thereby when irradiated by one or more source particles, and in particular to scanning electron microscopes

### BACKGROUND OF THE INVENTION

Scanning electron microscopes are used to evaluate properties of a sample by scanning it, i.e., irradiating it with source particles such as electrons, and detecting particles produced by the sample as a result of the irradiation.

In some applications evaluation of relevant properties requires irradiation with the source particles for an extended period of time, to the extent that damage may occur to the sample, and/or a buildup of negative charge on the sample due to electrons irradiated thereon may give rise to drift effects, thereby interfering with subsequent scanning. For example, material characterization of the sample, e.g., determining the material concentration and/or the thickness of thin layers at a location on the sample, may require irradiating a single location for dozens to hundreds of seconds in order for the sample to produce enough signals to perform a suitable evaluation.

### BRIEF SUMMARY OF THE INVENTION

According to an aspect of the presently disclosed subject matter, there is provided a scanning electron microscope configured to evaluate one or more properties of a sample, the sample comprising a plurality of repeating features, the scanning electron microscope comprising:
a scanning arrangement configured to scan a site on the sample by irradiating it with a plurality of source particles and detecting resulting signals produced by the sample; and
a controller configured to direct operation of the scanning electron microscope, and to evaluate one or more predetermined properties at the site at least partially based on measurements of the detected signals;
   the controller being further configured to:
direct the scanning arrangement to scan (i.e., irradiate with source particles and detects the resulting signals) equivalent sites of interest on each of the plurality of repeating features for a scan-duration, each of the scan-durations being substantially less than a predetermined acquisition-duration and the sum of the scan-durations being at least as long as the acquisition-duration, wherein evaluation of the one or more predetermined properties requires scanning the site of interest for the acquisition-duration;
aggregate measurements of the detected signals produced by each of the equivalent sites of interest; and
evaluate the one or more predetermined properties of the sites of interest on the plurality of repeating features based at least partially on the aggregated measurements.

According to another aspect of the presently disclosed subject matter, there is provided an inspection system configured to evaluate one or more properties of a sample, the sample comprising a plurality of repeating features, the inspection system comprising:
a scanning arrangement configured to scan a site on the sample by irradiating it with a plurality of source particles and detecting resulting signals produced by the sample; and
a controller configured to direct operation of the inspection system, and to evaluate one or more properties at the site at least partially based on measurements of the detected signals;
   the controller being further configured to:
direct the scanning arrangement to scan equivalent sites of interest on each of the plurality of repeating features for a scan-duration, each of the scan-durations being substantially less than a predetermined acquisition-duration and the sum of the scan-durations being at least as long as the acquisition-duration, wherein evaluation of the one or more predetermined properties requires scanning the site of interest for the acquisition-duration;
aggregate measurements of the detected signals produced by each of the equivalent sites of interest; and
evaluate the one or more predetermined properties of the sites of interest on the plurality of repeating features based at least partially on the aggregated measurements.

Herein the present disclose and appended claims, references to “features,” “plurality of repeating features,” etc., refer to the features whose equivalent sites are scanned and evaluated. In practice, the SEM may be configured to evaluate one or more properties of sites of interest on a set of repeating features by combining detected signals as described herein from equivalent sites of interest on a subset of features of the sample, and applying the evaluation to the entire set of repeating features including those not scanned, mutatis mutandis.

Either of the above aspects may be characterized as provided below.

The sum of all the scan-durations may be substantially equal to the acquisition-duration.

The scan-durations for the equivalent sites of interest may be substantially the same.

The features may be arranged in a regular pattern.

The controller may be configured to determine the location of each of the sites of interest prior to directing the scanning arrangement to scan it.

Determining the location of a site of interest may comprise operating the scanning electron microscope/inspection system to acquire an image of the feature which comprises the site of interest to be scanned.

Determining the location of a site of interest may comprise accounting for deviations of a feature which comprises the site of interest to be scanned.

Accounting for deviations may comprise implementing an adaptive algorithm which introduces suitable degrees-of-freedom for the expected variations in the shape of the feature to be scanned.

One or more of the predetermined properties may be used for material analysis.

The predetermined properties may comprise the percentage of a material in the sample at the site of interest.

The predetermined properties may comprise the thickness of the sample at the site of interest.

The scanning electron microscope/inspection system may be configured to implement energy-dispersive X-ray spectroscopy to facilitate evaluating the predetermined properties.

The scanning electron microscope/inspection system may be configured to implement wavelength-dispersive X-ray spectroscopy to facilitate evaluating the predetermined properties.

According to another aspect of the presently disclosed subject matter, there is provided a method of evaluating one or more predetermined properties of a plurality of repeating features of a sample, wherein evaluation of the predetermined properties requires scanning a site of interest on each of the repeating features for an acquisition-duration the method comprising:
providing an inspection system comprising a scanning arrangement configured to scan a site on the sample by irradiating it with a plurality of source particles, and to detect resulting signals produced by the sample;
directing the scanning arrangement to scan equivalent sites of interest on each of the plurality of repeating features for a scan-duration, each of the scan-durations being substantially less than the acquisition-duration, the sum of the scan-durations being at least as long as the acquisition-duration;
aggregating measurements of the detected signals produced by each of the equivalent sites of interest; and
evaluating the one or more predetermined properties of the sites of interest on the plurality of repeating features based at least partially on the aggregated measurements.

The inspection system may comprise a scanning electron microscope.

The sum of all the scan-durations may be substantially equal to the acquisition-duration.

The scan-durations for the equivalent sites of interest may be substantially the same.

The features may be arranged in a regular pattern.

The method may further comprise determining the location of each of the sites of interest prior to directing the scanning arrangement to scan it.

Determining the location of a site of interest may comprise operating the inspection system to acquire an image of the feature which comprises the site of interest to be scanned.

Determining the location of a site of interest may comprise accounting for deviations of a feature which comprises the site of interest to be scanned.

Accounting for deviations may comprise implementing an adaptive algorithm which introduces suitable degrees-of-freedom for the expected variations in the shape of the feature to be scanned.

One or more of the predetermined properties may be used for material analysis.

The predetermined properties may comprise the percentage of a material in the sample at the site of interest.

The predetermined properties may comprise the thickness of the sample at the site of interest.

The scanning electron microscope/inspection system may be configured to implement energy-dispersive X-ray spectroscopy to facilitate evaluating the predetermined properties.

The scanning electron microscope/inspection system may be configured to implement wavelength-dispersive X-ray spectroscopy to facilitate evaluating the predetermined properties.

### BRIEF DESCRIPTION OF THE DRAWINGS

In order to better understand the subject matter that is disclosed herein and to exemplify how it may be carried out in practice, embodiments will now be described, by way of non-limiting example only, with reference to the accompanying drawings, in which:

FIG. 1 is a schematic illustration of a scanning electron microscope according to the presently disclosed subject matter;

FIG. 2 illustrates a plurality of repeating features of a sample for evaluation according to the presently disclosed subject matter; and

FIG. 3 illustrates a plurality of repeating features comprising deviations.

### DETAILED DESCRIPTION OF THE INVENTION

The presently disclosed subject matter is generally directed towards scanning electron microscopes and other inspection systems used for scanning a sample in order to evaluate physical properties thereof, for example material properties.

A scanning electron microscope according to the presently disclosed subject matter has a scanning arrangement configured to scan the sample by irradiating it with particles and detecting particles emitted by the sample as a result, and a controller which is configured to evaluate properties of the sample based, inter alia, on parameters of the detected emitted particles. In order to mitigate effects which may arise from lengthy irradiation of the sample, in particular lengthy irradiation in a single location, the scanning electron microscope is configured to scan equivalent sites of interest on a plurality of repeating features of the sample, each for a short period of time, and to make a single evaluation which is relevant for all the equivalent sites of interest based on an aggregation of the signals emitted during each of the scans. In this way, properties of the features may be evaluated while avoiding negative effects which may arise from irradiating it for a longer period of time.

It will be appreciated that the preceding is provided as an introductory overview to provide a general synopsis of the presently disclosed subject matter. Accordingly, it is not to be construed as limiting. Similarly, the inclusion of specific details therein, exclusion of specific details therefrom, generalizations, particularizations, etc., are not to be construed as limiting.

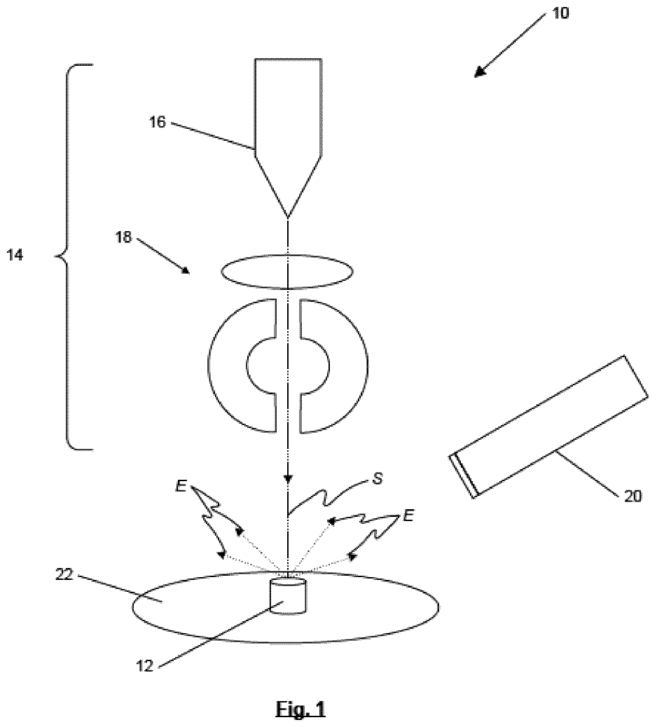

As illustrated in FIG. 1, there is provided a scanning electron microscope (SEM), which is generally indicated 10, configured to evaluate one or more properties of a sample 12. The SEM 10 may be configured, inter alia, to scan the sample 12 by irradiating it with source particles S, typically a focused beam of electrons; to detect one or more signals comprising emitted particles E produced by the sample when impinged upon by the source particles; and to evaluate the relevant properties based, inter alia, on parameters of the source particles and the emitted particles, for example as is known in the art. The emitted particles may be produced by the emission of particles produced from interactions of atoms of the sample 12 with the source particles, the reflection of source particles by the sample, scattering of source particles by the sample, etc.

The SEM 10 may be provided according to any suitable design. The SEM 10 comprises a scanning arrangement 14 configured, inter alia, to facilitate the evaluation of the one or more properties, e.g., by irradiating the sample 12 and detecting the one or more signals emitted therefrom. The SEM 10 further comprises a controller (not illustrated) configured to direct operation of the SEM and to perform the evaluation.

According to some examples, the scanning arrangement 14 comprises an electron gun assembly 16 configured to produce the beam of source particles and accelerate it toward the sample 12, a lens assembly 18 configured to direct and/or shape the beam of source particles, and a particle detector 20 configured to detect emitted particles produced by the sample 12 during scanning. The SEM 10 may further comprise a stage 22 for placement thereof of the sample 12 during scanning.

The electron gun assembly 16 may comprise a cathode configured to emit electrons when heated or subjected to an electric field, and an anode configured to accelerate the emitted electrons to form the beam of source particles. According to some examples, the electron gun assembly 16 is a thermionic emission gun, in which the cathode comprises a filament, for example made of tungsten or lanthanum hexaboride, which is configured to emit electrons when, thereby emitting electrons. According to other examples, the electron gun assembly is a field emission gun, in which the cathode comprises a single crystal tungsten with a sharply pointed tip, for example coated with a layer of zirconium oxide.

The lens assembly 18 may include one or more electromagnetic and/or electrostatic lenses, such as condenser lenses and objective lenses, configured to manipulate the trajectory and diameter of the beam of source particles.

The particle detector 20 may be configured to detect secondary electrons emitted from the sample 12 surface or within a few nanometers thereof, backscattered electrons produced by the elastic scattering of the source particles electrons with the atom nuclei, X-rays, or any other suitable type of emitted particles produced by the sample 12 during scanning. One or more suitable collectors (not illustrated) may be provided to attract emitted particles toward the particle detector 20, and optionally to accelerate them before impinging thereon. It will be appreciated that while a single particle detector 20 is illustrated positioned to one side of the stage 22, this is by way of example only, and in practice more than one particle detector may be provided. For example, different particle detectors 20 may be configured to detect different types of emitted particle, may be positioned in different locations, e.g., between the stage 22 and the electron gun assembly 16, etc., may be oriented a different angles, etc., for example as is known in the art, mutatis mutandis.

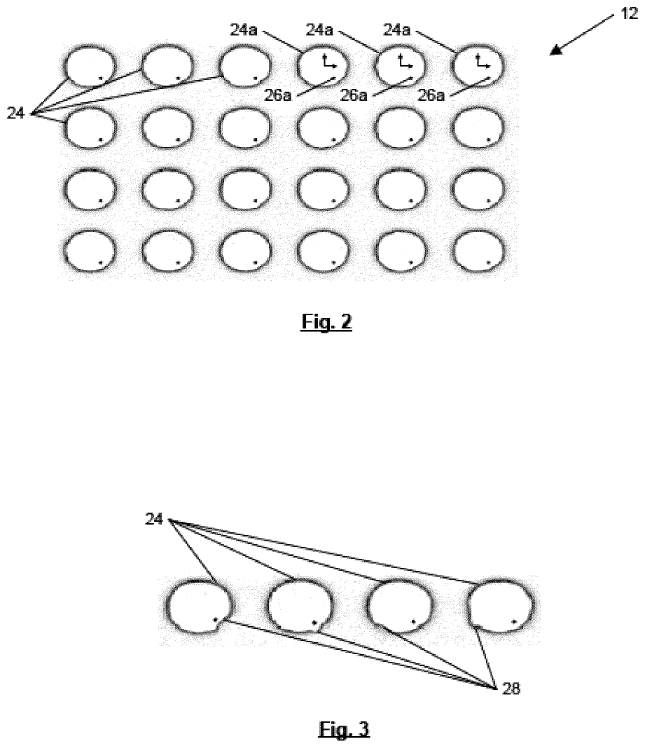

As illustrated in FIG. 2, the sample 12 may comprise a plurality of repeating features 24 which are substantially the same as each other, i.e., equivalent sites on each of the features are expected to have the same one or more properties of interest as one another, at least within an acceptable tolerance based, e.g., on the application for which the sample is being evaluated, the resolution of the SEM, etc.

A “property of interest” may include not only a physical property of the sample, but also the location, e.g., the material concentration of the sample at a specified site of interest on a feature may be a distinct property from the material concentration of the sample at a different site on the same feature.

The features 24 may be arranged in a regular pattern, e.g., wherein the distance between adjacent repeating features is substantially the same in each two-dimensional direction. According to some examples, the features 24 are arranged in a square or rectangular grid.

Ideally, equivalent sites may be located at similar locations on each of the repeating features 24; accordingly, the locations of respective equivalent sites on different features may ideally be predictable. For example, equivalent sites 26a, 26b, and 26c located on repeating features 24a, 24b, and 24c, respectively, are each in the same location (e.g., are located the same distance and the same direction from corresponding points on the repeating features, as indicated by the coordinate axes shown, wherein the origin of each is any suitable point on the respective feature), are expected to have the same one or more properties of interest as each other. (In the present disclosure, different elements indicated by a single reference numeral and distinguished by their trailing letters may be collectively indicated using the single reference numeral without a trailing letter, e.g., reference numeral 24 may be used to collectively features 24a and 24b.)

In practice, for example as illustrated in FIG. 3, some or all the repeating features 24 may not be completely uniform, for example comprising deviations 28 owing to manufacturing imprecisions. This is particularly relevant for patterned wafers, in which the features 24 themselves typically have sizes on the order of tens of microns; in such cases, deviations 28 of a few microns may be sufficiently large to shift the location of a site on one of the features 24 relative to the location of the corresponding equivalent site on another of the features which does not have the same deviations.

In order to collect enough information from the sample 12 to facilitate evaluating one or more of its properties of interest to a suitable level of quality (including, but not limited to, a specified signal-to-noise ratio) it is typically necessary to scan each of the features 24 at a site of interest thereon for an amount of time equal to a predetermined acquisition-duration. The acquisition-duration may be based, e.g., on parameters of the source particles, material properties of the sample, the property or properties of interest to be evaluated, the level of quality desired, etc.

The controller may be configured to facilitate evaluating a predetermined property at equivalent sites of interest on the features 24 to a suitable level of quality, without scanning any one of the features for the entire acquisition-duration. This may be useful, e.g., to reduce negative effects which may occur owing to extended irradiation. Such negative effects may include, but are not limited to, thermal damage, electrical drift due to a buildup of a charge on the surface of the sample, thermal drift due to thermal expansion and/or contraction, mechanical drift due to vibrations, friction, etc. While some negative effects (e.g., thermal damage) may affect the sample, others (e.g., drift) may affect the scanning process itself, for example by displacing the source particles, thereby degrading the quality of data obtained.

Accordingly, the controller may be configured to direct the electron gun assembly 16 of the scanning arrangement 14 to irradiate equivalent sites of interest (e.g., 26a, 26b, 26c, etc.) on each of the plurality of repeating features 24. Each of the equivalent sites of interest is irradiated for a scan-duration which is substantially less than the acquisition-duration; as noted above, the acquisition-duration would ordinarily be required to collect enough information, i.e., to detect a sufficient quantity of signals, from the sample to facilitate evaluating one or more properties of interest to a suitable level of quality. In particular, the scan-duration may be short enough such that one or more negative effects, which would otherwise occur if a site of interest were to be irradiated for the acquisition-duration, does not occur or is significantly mitigated.

Moreover, the sum of the scan-durations, i.e., the total amount of time that the sites of interest on all the features 24 are scanned, is at least as long as the acquisition-duration. According to some examples, the sum of the scan-durations is equal to or substantially equal to the acquisition-duration. In this connection, the meaning of the term “substantially equal” may include that each of the scan-durations is as short as possible given physical and/or practical limitations and/or that the sum of the scan-durations exceeds the acquisition-duration by an amount of time which is no greater than one of the scan-durations. According to some examples, the scan-durations are all substantially the same length of time, e.g., as close as possible within physical and/or practical limitations.

The controller is further configured to aggregate measurements of signals which are detected by the particle detector 20 during the scans of the sample at the equivalent sites of interest. As the total amount of time that the sites of interest are scanned is at least as long as the acquisition-duration, the aggregated measurements are expected to contain enough information for the one or more properties of interest to be evaluated to a suitable level of quality.

Accordingly, the controller is further configured to evaluate the one or more properties of interest based, inter alia, on the aggregated measurements. The evaluation of properties of interest so obtained may be of a similar level of quality as would be a reference evaluation obtained by a process in which a single site of interest is scanned for an amount of time equal to the acquisition-duration. According to some examples, for example wherein scanning a single site of interest for an amount of time equal to the acquisition-duration would cause sufficient drift to substantially degrade the quality of data obtained, the evaluation of properties of interest as described above may be of a higher level of quality comparted to that of a reference evaluation.

It is recognized that while the reduction/mitigation negative effects are expected to be reduced to the greatest extent when the scan-duration is as small as possible, neither the presently disclosed subject matter nor the scope of the appended claims are so limited. For example, physical and/or practical limitations may warrant scan-durations whose total far exceeds the acquisition-duration; proper evaluation may require that a minimum quantity of signals be detected from each of the equivalent sites of interest, thereby requiring a scan-duration which is longer than would be otherwise be necessary; etc.

According to some examples, the controller may be configured, prior to operating the scanning arrangement 14 to scan equivalent sites of interest as described above, to determine the location of the site of interest on each feature 24 which corresponds to the sites of interest on the other repeating features. According to some examples, the controller may be configured to implement an algorithm to facilitate determining the location of the equivalent site of interest on a feature 24 having significant deviations 28. This may comprise implementing an adaptive algorithm which introduces suitable degrees-of-freedom for the expected variations in the shape of the feature, for example as is known in the art. According to some examples, the controller is configured to use an image of each feature to determine the location of the equivalent site of interest thereon.

According to some examples, the controller may be configured to operate the SEM 10 to image each feature 24, for example as is known in the art, prior to scanning the site of interest thereon. The acquired image may be used, e.g., to determine the location of the equivalent site of interest on the feature 24 having for example significant deviation for example as discussed above, and/or to determine the location of the equivalent site of interest on the feature 24 while accounting for drift which may have been introduced, for example due to charge buildup from previous irradiations. According to some examples, the controller is configured to image a feature 24 immediately prior to scanning the site of interest thereon. According to some examples, the controller is configured to image a plurality of the features 24 prior to scanning their respective sites of interest; in this case, a new image should be acquired of the to-be-scanned features before, e.g., the buildup of charge since the last image acquisition is expected to lead to enough drift to substantially degrade the quality of data obtained.

According to some examples, the controller is configured to perform material analysis, for example determining material concentration (e.g., the percentage of germanium in a silicon-germanium sample) and/or the thickness of a layer at a site of interest.

According to some examples, the controller is configured to perform energy-dispersive X-ray spectroscopy and/or wavelength-dispersive X-ray spectroscopy, for example as is known in the art.

According to some examples, the scanning arrangement 14 is configured to accelerate the source particles with an accelerating voltage of at least about 5 kV. According to some examples, the source particles may be characterized by a current of at least about 2 nA.

It will be appreciated that while the presently disclosed subject matter refers to a scanning electron microscope, this is by way of example only, and in practice it may be implemented using any suitable inspection system for example as is known in the art, mutatis mutandis.

The term “duration” is used in the present description and appended claims to refer to a length of time, i.e., as a unit of measurement which quantifies the amount of time associated with the activity represented by its respective premodifier. Accordingly, it is not to be construed as referring to the actual period or moment in time in which the activity occurs.

In the presently disclosed subject matter, the meaning of the term “substantially,” “significantly,” or any other similar language may include, if not defined otherwise and/or clear from context, a characterization of its antecedent as being to a sufficient extent that the evaluation of the properties of interest is measurable, and/or as being consequential given the requirements of the application.

It will be appreciated that while herein the specification and claims the term “controller” is used with reference to a single element, it may comprise a combination of elements, which may or may not be in physical proximity to one another, without departing from the scope of the presently disclosed subject matter, mutatis mutandis. In addition, disclosure herein (including recitation in the appended claims) of a controller carrying out, being configured to carry out, or other similar language, implicitly includes other elements of the SEM 10 carrying out, being configured to carry out, etc., those functions—alone, in concert with the controller, in concert with other elements of the SEM, in concert with one or more external devices, etc.—without departing from the scope of the presently disclosed subject matter, mutatis mutandis.

It will be recognized that examples, embodiments, modifications, options, etc., described herein are to be construed as inclusive and non-limiting, i.e., two or more examples, etc., described separately herein are not to be construed as being mutually exclusive of one another or in any other way limiting, unless such is explicitly stated and/or is otherwise clear. Those skilled in the art to which this invention pertains will readily appreciate that numerous changes, variations, and modifications can be made without departing from the scope of the presently disclosed subject matter, mutatis mutandis.

1. A scanning electron microscope configured to evaluate one or more properties of a sample, the sample comprising a plurality of repeating features, the scanning electron microscope comprising:
a scanning arrangement configured to scan a site on the sample by irradiating it with a plurality of source particles and detecting resulting signals produced by the sample; and
a controller configured to direct operation of the scanning electron microscope, and to evaluate one or more predetermined properties at the site at least partially based on measurements of the detected signals;
the controller being further configured to:
direct the scanning arrangement to scan equivalent sites of interest on each of the plurality of repeating features for a scan-duration, each of the scan-durations being substantially less than a predetermined acquisition-duration and the sum of the scan-durations being at least as long as the acquisition-duration, wherein evaluation of the one or more predetermined properties requires scanning the site of interest for the acquisition-duration;
aggregate measurements of the detected signals produced by each of the equivalent sites of interest; and
evaluate the one or more predetermined properties of the sites of interest on the plurality of repeating features based at least partially on the aggregated measurements.

2. The scanning electron microscope according to claim 1, wherein the sum of all the scan-durations is substantially equal to the acquisition-duration.

3. The scanning electron microscope according to claim 1, wherein the scan-durations for the equivalent sites of interest are substantially the same.

4. (canceled)

5. The scanning electron microscope according to claim 1, wherein the controller is configured to determine the location of each of the sites of interest prior to directing the scanning arrangement to scan it.

6. The scanning electron microscope according to claim 5, wherein determining the location of a site of interest comprises operating the scanning electron microscope to acquire an image of the feature which comprises the site of interest to be scanned.

7. The scanning electron microscope according to claim 5, wherein determining the location of a site of interest comprises accounting for deviations of a feature which comprises the site of interest to be scanned.

8. The scanning electron microscope according to claim 7, wherein accounting for deviations comprises implementing an adaptive algorithm which introduces suitable degrees-of-freedom for the expected variations in the shape of the feature to be scanned.

9. The scanning electron microscope according to claim 1, wherein one or more of the predetermined properties is used for material analysis.

10. The scanning electron microscope according to claim 9, wherein the predetermined properties comprise the percentage of a material in the sample at the site of interest and/or the thickness of the sample at the site of interest.

11. (canceled)

12. The scanning electron microscope according to claim 1, being configured to implement energy-dispersive X-ray spectroscopy and/or X ray spectroscopy to facilitate evaluating the predetermined properties.

13. (canceled)

14. A method of evaluating one or more predetermined properties of a plurality of repeating features of a sample, wherein evaluation of the predetermined properties requires scanning a site of interest on each of the repeating features for an acquisition-duration the method comprising:
providing a scanning electron microscope comprising a scanning arrangement configured to scan a site on the sample by irradiating it with a plurality of source particles, and to detect resulting signals produced by the sample;
directing the scanning arrangement to scan equivalent sites of interest on each of the plurality of repeating features for a scan-duration, each of the scan-durations being substantially less than the acquisition-duration, the sum of the scan-durations being at least as long as the acquisition-duration;
aggregating measurements of the detected signals produced by each of the equivalent sites of interest; and
evaluating the one or more predetermined properties of the sites of interest on the plurality of repeating features based at least partially on the aggregated measurements.

15. (canceled)

16. The method according to claim 14, wherein the scan-durations for the equivalent sites of interest are substantially the same.

17. The method according to claim 14, wherein the features are arranged in a regular pattern.

18. The method according to claim 14, further comprising determining the location of each of the sites of interest prior to directing the scanning arrangement to scan it.

19. The method according to claim 18, wherein determining the location of a site of interest comprises operating the scanning electron microscope to acquire an image of the feature which comprises the site of interest to be scanned.

20. The method according to claim 14, wherein determining the location of a site of interest comprises accounting for deviations of a feature which comprises the site of interest to be scanned.

21. The method according to claim 20, wherein accounting for deviations comprises implementing an adaptive algorithm which introduces suitable degrees-of-freedom for the expected variations in the shape of the feature to be scanned.

22. The method according to claim 14, wherein one or more of the predetermined properties is used for material analysis.

23. The method according to claim 22, wherein the predetermined properties comprise the percentage of a material in the sample at the site of interest and/or the thickness of the sample at the site of interest.

24. (canceled)

25. The method according to claim 14, further comprising implementing energy-dispersive X-ray spectroscopy and/or X ray spectroscopy to facilitate evaluating the predetermined properties.

26. (canceled)
